(19) United States
(12) Patent Application Publication
(10) Pub. No.: US 2003/0112168 A1
(43) Pub. Date: Jun. 19, 2003

(54) Analog to digital converter using a programmable interpolator and method thereof

(75) Inventor: Hyung-Hoon Kim, Songnam-shi (KR)

Correspondence Address: Paul J. Farrell, Esq., DILWORTH & BARRESE, LLP, 333 Earle Ovington Blvd., Uniondale, NY, 11553, US

(73) Assignee: SAMSUNG ELECTRONICS CO., LTD., KYUNGKI-DO (KR)

(21) Appl. No.: 10/231,616

(22) Filed: Aug. 30, 2002

(30) Foreign Application Priority Data
Dec. 7, 2001 (KR) 2001-77526

(51) Int. Cl. H03M 1/12

(52) U.S. Cl. 341/155

(57) ABSTRACT

An analog to digital converter, which includes a folding block for converting analog signals inputted to folding signals; an interpolation block for interpolating the folding signals by a predetermined control signal, for adjusting number of the interpolated folding signals, and for outputting the adjusted folding signals; a converter block for converting the interpolated folding signals to digital signals; a switching block switch controlling authorization of the signals that are outputted from the interpolation unit by an external control signal; an encoding block for converting the digital signals that are outputted from the converting unit to binary data; an error-correction block for correcting any error in the binary data; and an output buffer block for buffering output of the error-corrected binary data.

### PRIORITY

This application claims priority to an application entitled “Analog to digital converter using programmable interpolator and method thereof” filed in the Korean Industrial Property Office on Dec. 7, 2001 and assigned Serial No. 2001-77526, the contents of which are hereby incorporated by reference.

### BACKGROUND OF THE INVENTION

1. Field of the Invention

The present invention relates generally to an analog to digital converter and method thereof, and in particular, to an analog to digital converter in a baseband frequency domain of a mobile communication terminal and method thereof.

2. Description of the Related Art

In general, of the purpose of a system affects resolution and maximum conversion speed of an analog to digital converter (hereinafter, it is referred to “A/D Converter”) for use in mobile communication terminals. For example, when a system is designed to process a voice signal, a sigma-delta A/D Converter, which has high resolution despite of low conversion speed, has been used. When image signals are to be processed, however, the conversion speed is the main factor to consider, not the resolution. In this case, A/D Converts with a pipe-line, a two-stage flash, or a folding-interpolating method is preferred. Therefore, the type of A/D Converter to be used is determined in accordance with the resolution and conversion speed of the converter. Naturally, there are many occasions where both the resolution and the conversion speed must be satisfied.

A typically used A/D Converter in mobile communication terminals is a commercially available programmable A/D Converter like the “TLV1562”, manufactured and sold by Texas Instrument Company. FIG. 1 illustrates the internal configuration of the “TLV1562”. That particular A/D Converter illustrated in FIG. 1 is applicable to WLL (Wireless Local Loop), mobile solution, and so forth. An A/D Converter with the same configuration as illustrated in FIG. 1 includes another A/D Converter having different resolution in one chip, and at the time of initiation, it converts analog signals to digital signals with the fixed resolution. Further, if the converted resolution is not sufficient for a DSP (Digital Signal Processor), the A/D Converter is capable of changing the resolution of the A/D Converter inside of the chip to be appropriate for the DSP. However, this applies only when the A/D Converter like the one illustrated in FIG. 1 has a plurality of other A/D Converters installed in a single chip.

Currently, to have proper specification for the tri-mode terminal, the A/D Converter for UMTS (Universal Mobile Telecommunications System: Asynchronous Code Division Multiple Access system) based modem has 6-bit resolution and high conversion speed. Different from this, the A/D Converter for GSM (the Global System for Mobile communications) or GPRS (General Packet Radio Service) based modem has 10-bit resolution and low conversion speed. Accordingly, to satisfy trade-off, resolution of the A/D Converter should be changeable.

Most A/D converters currently being used are driven by voltage, so the area occupied by the A/D converter inside of the chip is very large and its power consumption is also very high. Against the recent trend in the mobile communication system, that is, miniaturation and low power consumption, the system chip limits the entire system's scale.

Alternatively, there is a folding-interpolation structured A/D Converter that is driven by current. This A/D Converter processes signals using current, not voltage, so additional circuits are necessary for the signal processing than in the conventional voltage system. The A/D Converter's conversion process using the folding-interpolation method is largely divided into a preprocessing and a processing in which the signals generated from the preprocessing are processed. Resolution of the A/D Converter with the folding-interpolation system changes depending on a folding rate, a folding block rate, and an interpolation rate. In other words, any change in more than one factor of the folding rate, the folding amplification rate, and the interpolation rate can change the resolution of the A/D Converter.

### SUMMARY OF THE INVENTION

It is, therefore, an object of the present invention to provide an analog to digital converter using an interpolator and method thereof, thereby controlling resolution of the converter by changing an interpolation rate.

Another object of the present invention is to provide an analog to digital converter for use in a mobile communication terminal using a folding-interpolator, and a method for changing an interpolation rate of the converter.

Still another object of the present invention is to provide an analog to digital converter using an interpolator, and method for changing resolution and conversion speed of the converter by using an interpolation circuit that controls a current flow to current mirrors and an amount of the current flowing to each current mirror.

To achieve the above objects, there is provided an analog to digital converter, comprising: a folding block for converting analog signals inputted to folding signals; an interpolation block for interpolating the folding signals by a predetermined control signal, for adjusting number of the interpolated folding signals, and for outputting the adjusted folding signals; a converter block for converting the interpolated folding signals to digital signals; a switching block for switch controlling authorization of the signals that are outputted from the interpolation unit by an external control signal; an encoding block for converting the digital signals that are outputted from the converting unit to binary data; an error-correction block for correcting any error in the binary data; and an output buffer block for buffering an output of the error-corrected binary data.

### BRIEF DESCRIPTION OF THE DRAWINGS

The above and other objects, features, and advantages of the present invention will become more apparent from the following detailed description when taken in conjunction with the accompanying drawings in which:

FIG. 1 is a diagram illustrating a configuration of an analog to digital converter (A/D Converter) for use in mobile communication terminals in the related art;

FIG. 2 is a diagram illustrating a block configuration of an A/D Converter using a programmable interpolator in accordance with a preferred embodiment of the present invention;

FIG. 3 is a diagram illustrating a detailed configuration of the interpolation block illustrated in FIG. 2;

FIG. 4A through FIG. 4C are waveform diagrams illustrating characteristics of an interpolation operation performed by the interpolation block having the configuration illustrated in FIG. 3 under a control signal;

FIG. 5A is a diagram illustrating detailed configuration of the folding block illustrated in FIG. 2;

FIG. 5B is a diagram illustrating output waveform characteristics of the folding block;

FIG. 6 is a diagram illustrating a detailed configuration of a switching block illustrated in FIG. 2; and

FIG. 7B is a diagram illustrating an RF board of mobile communication terminals in the related art; and

FIG. 7B is a diagram illustrating an RF board of a terminal mounted with an A/D Converter in accordance with a preferred embodiment of the present invention.

### DETAILED DESCRIPTION OF THE PREFERRED EMBODIMENT

A preferred embodiment of the present invention will be described herein below with reference to the accompanying drawings. In the following description, well-known functions or constructions are not described in detail since they would obscure the invention in unnecessary detail.

A conversion procedure for an analog to digital converter (A/D Converter) using a folding-interpolation method is divided to a preprocessing step and a step for processing signals generated in the preprocessing step. As described above, resolution of the A/D Converter based on the folding-interpolation method changes depending on a folding rate, a folding block rate, an interpolation rate, and so forth. Particularly, in the present invention, the resolution of the A/D Converter is changed by varying the interpolation rate. To do so, the interpolation rate controlling circuit copies a current value of a base current-mirror to the circuit under an external input signal (DSP: Digital Signal Processor), and makes the current amount flowing in each current mirror determined by a joint area of each CMOS element. Therefore, as for the interpolation circuit, the interpolation rate influences the number of folding signals that determine resolution of the entire converter, and as the resolution decreases, the current value of the entire circuit and the number of elements to be operated are decreased, which in turn increases the conversion speed of the entire converter.

As aforementioned, the folding-interpolation A/D Converter capable of varying resolution requires a band-gap base voltage generating circuit, a folding signal generating circuit, an interpolation circuit, a comparator, a digital encoder, an error correction circuit, an output buffer, an internal clock generator, and a switch circuit for conducting as an interface in each circuit. Here, the resolution is determined by the folding circuit, which generates folding signals for the first time, and by the interpolation circuit, which increases the number of generated folding signals up to the resolution that the entire analog-digital conversion system requires. Since the interpolation circuit is controlled by the DSP control signal of the outside, the interpolation rate can be also changed by the same.

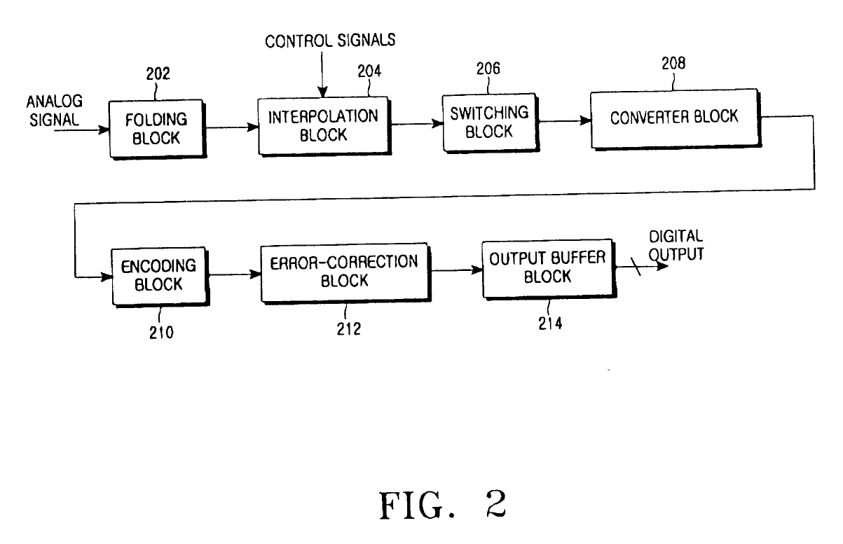

FIG. 2 is a diagram illustrating the entire block configuration of the folding-interpolation A/D Converter having variable resolution. Referring to FIG. 2, a folding block 202 receives analog signals that are converted to folding signals. An interpolation block 204, under the control of external control signals, varies an interpolation rate of the folding signals generated by the folding block 202. A switching block 206 is used for outputting the interpolation rate that was varied at the interpolation block 204. A converter block 208 converts the folding signals with the varied interpolation from the switching block 206 into digital data. An encoding block 210 converts the digital data outputted form the converter block 208 to binary data. An error-correction block 212 corrects errors in the binary data that is outputted from the encoding block 210. Finally, an output buffer block 214 buffers the error-corrected binary data and outputs the buffered data.

When analog signals are inputted, the folding-interpolation system A/D Converter having the same configuration with that of FIG. 2, unlike the general pipe-line or two-stage flash structured analog-digital conversion system, converts the analog signals to sine wave signals, or folding signals, at the folding block 202, which is preprocessing block. This happens because the signal-to-noise ratio needs to be increased before the analog signals are converted to digital signals. Here, the resolution of the entire conversion system is determined depending on the number of the folding signals. Normally, the number of folding signals to satisfy the resolution of the entire conversion system is determined by the number of folding amplifiers, the number of folding blocks gathered by the amplifiers, and the interpolation rate of the interpolation block 204.

Once the analog signals are authorized to the folding block 202, the folding block 202 converts the inputted analog signals to as many folding signals as there are folding amplifiers and the folding block rate.

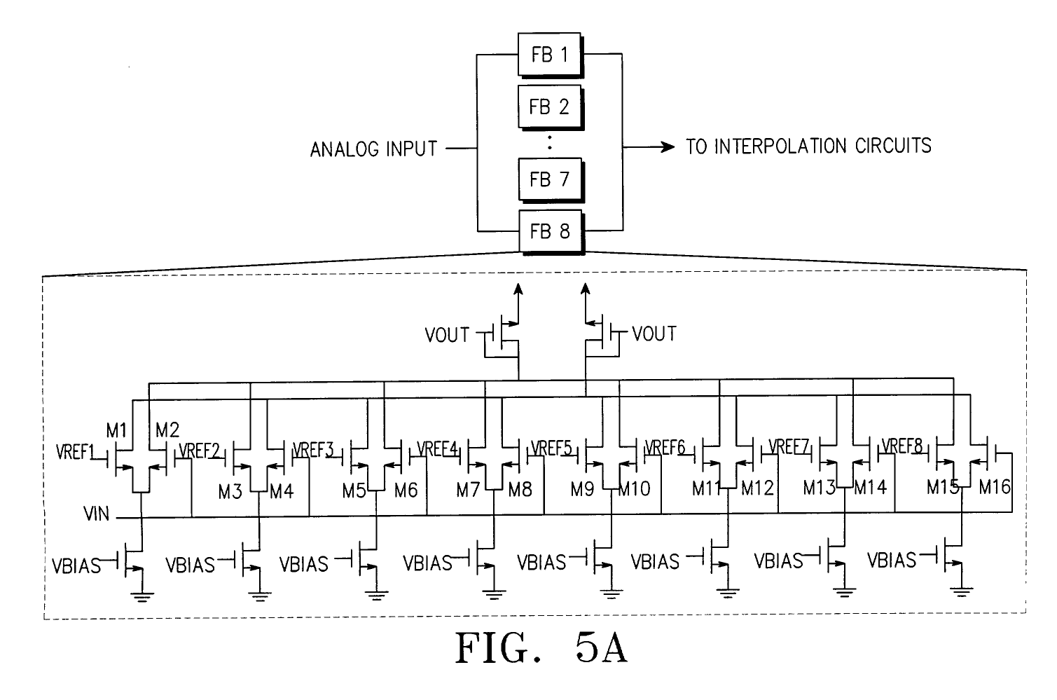

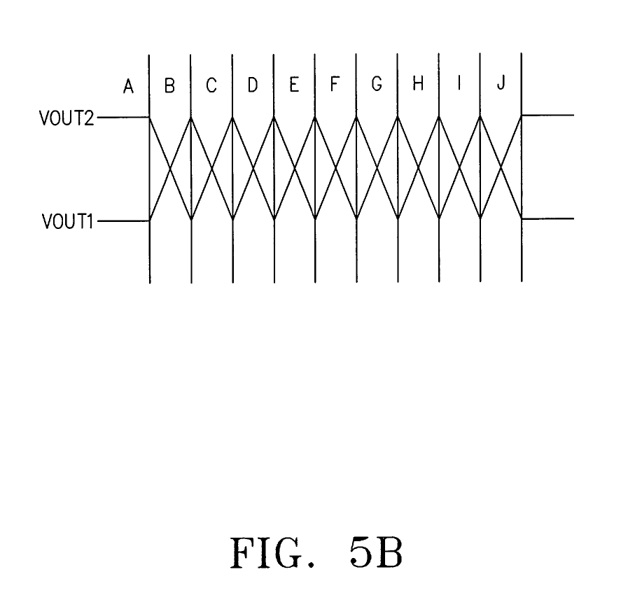

FIG. 5A is a diagram illustrating a configuration of the folding block 202 as illustrated in FIG. 2. Referring to FIG. 5A, the folding block 202 for generating the folding signals is comprised of parallel folding amplifiers for controlling the current flow in a one-stage amplifier operated by the voltage of inputted analog signals and the reference offset signal. For example, FIG. 5A shows 8 folding blocks FB1 through FB8. Each folding block includes 8 folding amplifiers that are arranged in parallel, and every folding amplifier includes independent reference offset signals Vref1 through Vref8 corresponding to the eight folding amplifiers. Therefore, according to the principle of generating folding signals, when analog signals are inputted, these inputted signals are compared with the reference offset signals, and then the current of the voltage with more signals is increased, while the current of the voltage with fewer signals is decreased.

As to the operation principle of the folding block 202, as illustrated in FIG. 5A, the reference bias current values of each folding amplifier M1-M2, M3-M4, M5-M6, M7-M8, M9-M10, M11-M12, M-13-M14, and M15-M16 are determined through Vbias. These reference offset values Vref1 through Vref8are authorized to Vin and the folding blocks FB1 through FB8 at the same time, and according to the result thereof, the current values vary. For example, when the voltage value inputted from the folding block FB1 is 0.4v. Then, the value from the Vref1 through the Vref8 maintains the equal space, 0.05v. That is, Vref 1=0.05, Vref 2=0.1, Vref 3=0.15, Vref 4=0.2, Vref 5=0.25, Vref 6=0.3, Vref 7=0.35, and Vref 8=0.4. Under the same condition, suppose that sine wave of which Vin is in range of from 0 to 0.8 is authorized. In such a case, the Vin and Vrefn of the 8 folding amplifiers would be simultaneously compared in real time. For instance, if Vin is less than 0.05v, current flows only into MOS transistors on the left side of the folding blocks FB1 through FB8, each including differential amplifiers M1-M2, M3-M4, M5-M6, M7-M8, M9-M10, M11-M12, M-13-M14, and M15-M16. However, if the input voltage is authorized as the Vin is greater than 0.05 and less than 0.1, the current flowing to M2 is increased. And, if the Vin is greater than 0.1, the current flowing to M2 is gradually decreased. In this case, the current flows into M3, M5, M7, M9, M11, M13 and M15. Accordingly, to obtain the same folding wave form with that illustrated in FIG. 5B, current values of the folding wave form are obtained as shown in Table 1 below.

TABLE 1

| Change of Vin | ON | OFF |
|---|---|---|
| A (0) | M1, M3, M5, M7 | M2, M4, M6, M8 |
| B (0 → 0.05) | M2 (increase), M3, M5, M7 | M1 (decrease), M4, |
| | | M6, M8 |
| C (0.05 → 0.1) | M2 (decrease), M3, M5, | M1 (increase), M4, |
| | M7 | M6, M8 |
| D (0.1 → 0.15) | M1, M4 (increase), M5, M7 | M2, M3 (decrease), |
| | | M6, M8 |
| B (0.15 → 0.2) | M1, M4 (decrease), M5, | M2, M3 (increase), |
| | M7 | M6, M8 |
| F (0.2 → 0.25) | M1, M3, M6 (increase), M7 | M2, M4, M5 |
| | | (decrease), M8 |
| G (0.25 → 0.3) | M1, M3, M6 (decrease), | M2, M4, M5 |
| | M7 | (increase), M8 |
| H (0.3 → 0.35) | M1, M3, M5, M8 (increase) | M2, M4, M6, M7 |
| | | (decrease) |
| I (0.35 → 0.4) | M1, M3, M5, M8 | M2, M4, M6, M7 |
| | (decrease) | (increase) |
| J (0.4 → higher) | M2, M4, M6, M8 | M1, M3, M5, M7 |

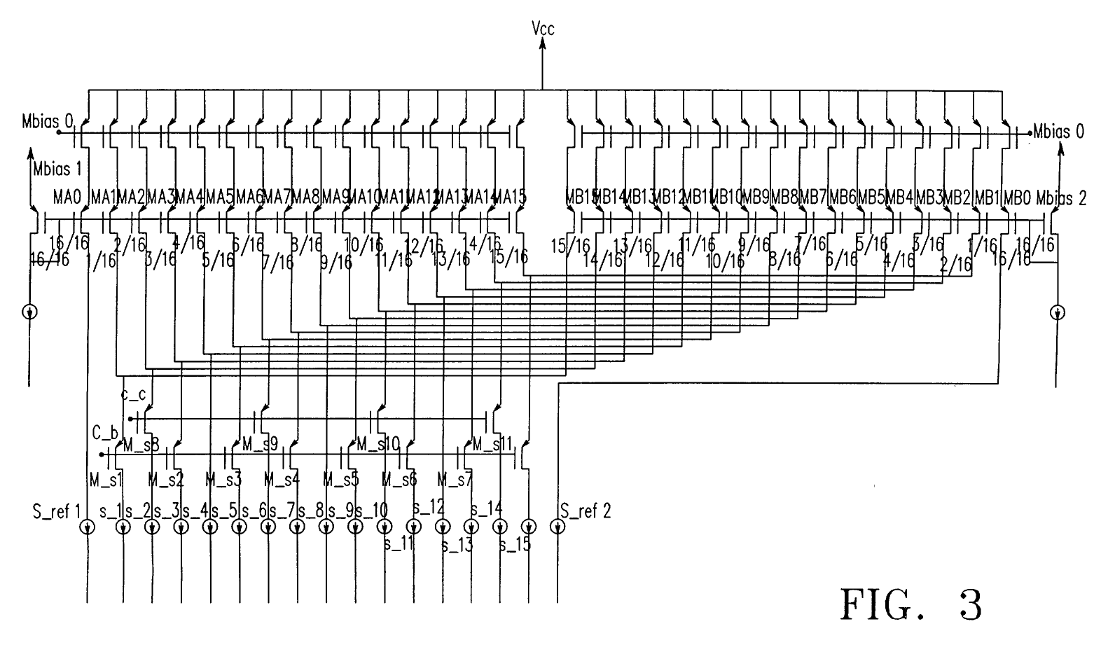

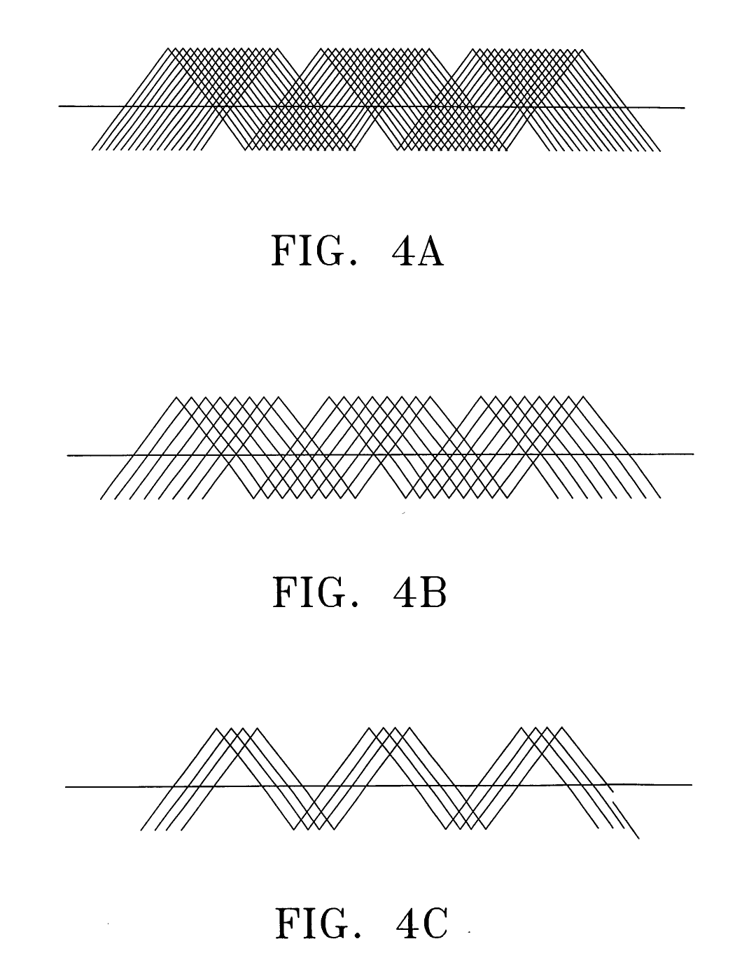

Thus, generated folding signals are authorized to the interpolation block 204, where the interpolation rate of the folding signals, under the externally authorized control signals, is varied. FIG. 3 illustrates a configuration of the interpolation block 204. Also, FIGS. 4A through 4C are output wave form diagrams for explaining characteristics of the interpolation rate's variation controlled by the external control signal at the interpolation block that has the same configuration illustrated in FIG. 3.

With reference to FIG. 3, the number of the folding signals can be controlled by the external control signal. The interpolation block 204, as illustrated in FIG. 3, is supposed to have a resolution of 16 at the most. Thus the first transistor series MA0 through MA15 include 16 resolutions and so does the second transistor series MB0 through MB15. The transistor Mbias 1 and the transistor Mbias 2 supply bias power to the first transistor series and the second transistor series, respectively. Here, the first transistor series and the second transistor series could be an interpolator. The MA0 of the first transistor series and the MB0 of the second transistor series are outputted with original current value, respectively, and the MA1, MA2, MA3, . . . , MA14, and MA15 of the first transistor series are connected to corresponding MB15, MB14, MB13, . . . , MB2, and MB1 of the second transistor series, respectively.

As to the operation principle of the interpolation block 204, the interpolator according to the present invention includes 32 PMOS transistors as is illustrated in FIG. 3, and MA series transistors and MB series transistors compose 16 pairs of current mirrors that are combined according to an aspect ratio. On the other hand, the current flow S_{—}1 through S_{—}15 generated in-between S_ref1 and S_ref2 by the current mirror is controlled by each switch. More specifically, as to the reference current I_ref1 and 1_ref2, current is generated to be proportional to the joint area of each transistor. With regards to I_ref1, if the joint area of MA (0-15) transistors is 16/16, the current flow is the same with the reference current I_ref1*(16/16) or I_ref1*1. Moreover, if the joint area is 15/16, the current flow is I_ref1*(15/16), and if the joint area is 1/16, the current flow is I_ref1(1/16). The same principle also applies to the I_REF2. Therefore, if the joint area of MA (0-15) transistors is 16/16, the current flow is the same with the reference current I_ref2. Similarly, if the joint area is 15/16, the current flow is I_ref2*(15/16), and if the joint area is 1/16, the current flow is I_ref2(1/16). Summing up these value, the current that actually flows between S_ref1 and S_ref2 are I_ref1 (15/16)+I_ref2 (1/16), I_ref1 (14/16)+I_ref2 (2/16), I_ref1 (13/16)+I_ref2 (3/16), etc.

The first control transistor series Ms1 through Ms7, and the second control transistor series Ms8 through Ms11 are connected to each other as shown in Table 2 below. Here, the first and the second control transistor series could be selectors for selecting interpolation rate.

TABLE 2

| 1^{st} Control | | Control | 2 Control | | Control |
|---|---|---|---|---|---|
| Transistor | Input | Signal | Transistor | Input | Signal |
| Ms1 | MA1, MB15 | Cb | Ms9 | MA1, MB15 | Ca |
| Ms2 | MA3, MB13 | | Ms10 | MA1, MB15 | |
| Ms3 | MA5, MB11 | | Ms11 | MA1, MB15 | |
| Ms4 | MA7, MB9 | | Ms12 | MA1, MB15 | |
| Ms5 | MA9, MB7 | | | | |
| Ms6 | MA11, MB5 | | | | |
| Ms7 | MA13, MB3 | | | | |
| Ms8 | MA15, MB1 | | | | |

As shown in Table 2, the interpolation block 204 controls each interpolation current signal under the externally authorized control signals, Ca and Cb. When the control signals Ca and Cb are turned on, the first control transistors Ms1 through Ms8, and the second control transistors Ms9 through Ms12 are all turned on. Then, 16 output paths are formed for 16 signals that are generated by the first and the second transistor series. Therefore, the interpolation rate of the folding signals in this case becomes 16. FIG. 4A is a waveform illustrating output characteristics when the controls signals Cb and Ca are all turned on. Meanwhile, if the control signal Cb is off, and the control signal Ca is on, the first control transistors Ms1 through Ms8 are all off, but the second control transistors Ms9 through Ms12 are on. Then, the signal output paths are formed for 8 out of 16 signals generated through the first and the second transistor series. Therefore, the interpolation rate of the folding signals becomes 8. FIG. 4B is a waveform illustrating output characteristics when the control signal Cb is off, while the control signal Ca is on. Lastly, if both the control signals Cb and Ca are off, both the first control transistors Ms1 through Ms8 and the second control transistors Ms9 through Ms12 are off. In such a case, only 4 signal output paths are formed for 4 out of 16 signals generated from the first and the second transistor series. Accordingly, the interpolation rate of the folding signals becomes 4. FIG. 4C is a waveform illustrating output characteristics when both the control signals Cb and Ca are off.

As stated above, the interpolation block 204 can vary interpolation rate of the folding signals inputted in accordance with the state of the externally authorized control signals Cb and Ca. This also implies that the interpolation block 204 can also vary resolution of the A/D converter, since the resolution is proportional to the interpolation rate.

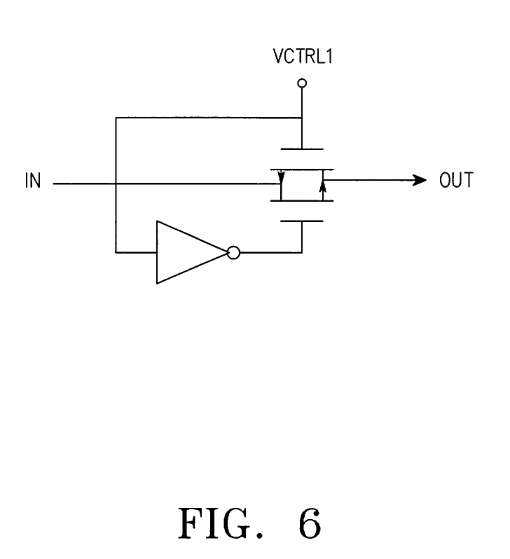

Therefore, the variably interpolated signals are authorized to the switching block 206. FIG. 6 illustrates the configuration of the switching block 206 in accordance with the present invention. Referring to FIG. 6, the switching block 206 is a pass-transistor switch block complemented with NMOS (n-channel enhancement-type MOSFET) and PMOS (p-channel enhancement-type MOSFET). The output of the switching block 206 is connected to the converter block 208 behind. NMOS and PMOS of the switching block 206 are turned on/off according to an externally authorized control signal Vctrl1, and controls the signal paths that are outputted from the interpolation block 204. As aforementioned, there are 2 components authorizing control signals by the control block DSP, one of them is the control signals Ca and Cb for controlling interpolation rate of the interpolation block 204, and the other is the control signal Vctrl11 for controlling switching as the output of the interpolation block 204 is transferred to the converter block 208.

As a result, increased folding signals in the interpolation block 204 are authorized to the converter block 208 through the switching block 206, and the converter block 208 converts the signals to digital data. Specifically, the converter block 208 converts the folding signals that are increased by the interpolation block 204 to Gray-code digital data. Then, the encoding block 210 encodes the Gray-code digital signals that are outputted from the converter block 208 to binary data. The relationship between Gray-code and Binary-code is shown in Table 3 below.

TABLE 3

| | Gray-code | Binary-code |
|---|---|---|
| 0 | 0000 | 0000 |
| 1 | 0001 | 0001 |
| 2 | 0011 | 0010 |
| 3 | 0010 | 0011 |
| 4 | 0110 | 0100 |
| 5 | 0111 | 0101 |
| 6 | 0101 | 0110 |
| 7 | 0100 | 0111 |
| 8 | 1100 | 1000 |
| 9 | 1101 | 1001 |

Afterwards, the error-correction block 212 corrects any error in the binary digital signals that are outputted from the encoding block 210, and the output buffer block 214 outputs the error-corrected digital signals after synchronizing them.

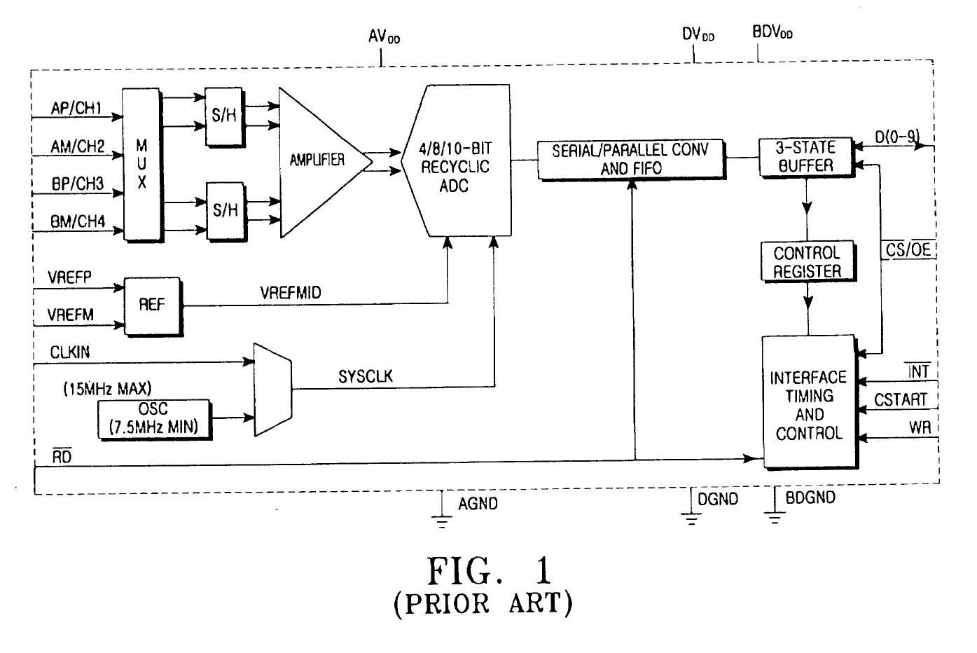

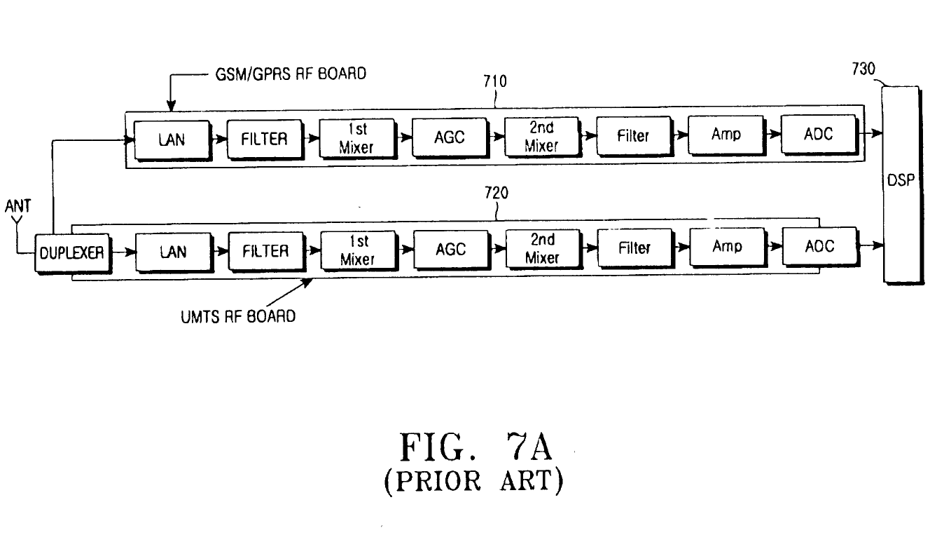

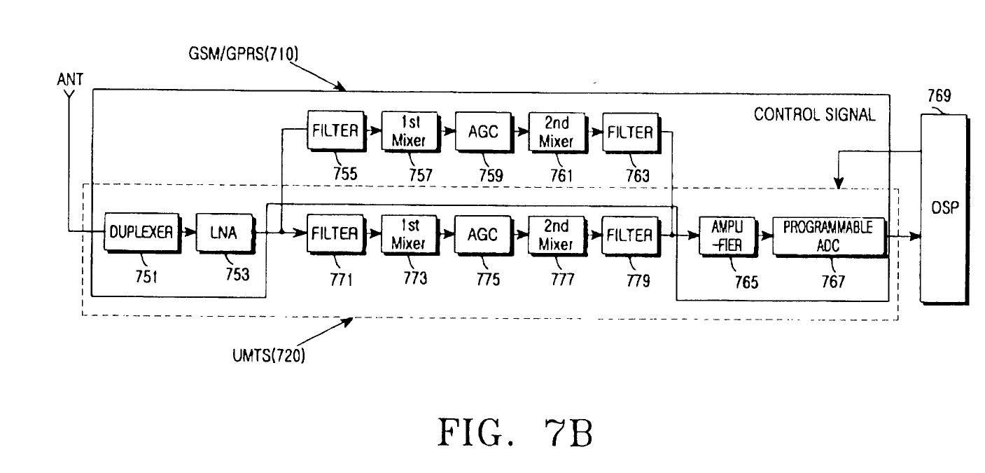

FIG. 7A is a diagram of an RF block of a terminal that adopts both UMTS and GSM/GPRS systems using the A/D Converter illustrated in FIG. 1 in the related art. Here, if the RF board 710 is for use of GSM/GPR, the RF board 720 can be the RF board for use of UMTS as well. Here, A/D Converters 715 and 725 have the same configuration illustrated in FIG. 1. Accordingly, when the RF signals having two different kinds of systems are to be provided to a terminal, independent A/D Converters have to be used, since the resolution of the A/D Converter illustrated in FIG. 7A is not variable.

However, an A/D Converter according to the present invention has a resolution that varies as needed, and can embody the RF board as illustrated in FIG. 7B.

Referring to FIG. 7B, a duplexer 751 inputs a receiving band's signals from an antenna ANT, and an LNA (Low Noise Amplifier) 753 amplifies the received signals to low noise and outputs the noise. The GSM/GPRS using board 710 includes a filter 755, a first mixer 757, an AGC (Automatic Gain Controller) 759, a second mixer 761, and a filter 763. The UMTS using board 720 includes a filter 771, a first mixer 773, an AGC 775, a second mixer 777, and a filter 779. Since the boards 710 and 720 have different frequency bands from each other, they have independent configurations for top-down conversion, that is, converting received RF signals to baseband. In other words, the received RF signals are converted to baseband signals by frequency down conversion of the corresponding boards 710 and 720 through the first mixers 757 and 773 and the second mixers 761 and 777. The amplifier 765 amplifies the output of the filters 763 and 779 and outputs the amplified baseband signals to the A/D converter 767[Please be informed that the amplifier 765 amplifies the output of the filter 763 and 779 within desired input level of the A/D converter 767. And, the amplified baseband signals are authorized to the A/D Converter 767. Here, the A/D Converter 767 has the same configuration as illustrated in FIG. 2, and this means that the A/D Converter 767 can vary its resolution under external control.

Prior to this invention, to embody an RF system applicable to both UMTS and GSM/GPRS, two RF boards for each mode were necessary. However, with the A/D Converter 767 of the present invention, if the same, some RF boards can be used in common, and this decreases a number of components of the system.

In conclusion, using the programmable interpolator, the A/D Converter can vary the interpolation of the data converter, and adjust the resolution as data goes through any changes. Specifically, the resolution of the A/D Converter used in each mode of the mobile communication terminal can be varied by a control signal, and therefore, the A/D Converter can be used regardless of UMTS, GSM, or GPRS by setting DSP.

While the invention has been shown and described with reference to a certain preferred embodiment thereof, it will be understood by those skilled in the art that various changes in form and details may be made therein without departing from the spirit and scope of the invention as defined by the appended claims.

What is claimed is:

1. An analog to digital converter (A/D Converter), comprising:
a folding block for converting inputted analog signals to folding signals;
an interpolation block for interpolating the folding signals, for adjusting a number of the interpolated folding signals by a predetermined control signal and for outputting the interpolated folding signals; and
a converter block for converting the interpolated folding signals to digital signals.

2. The A/D Converter as claimed in claim 1, wherein the interpolation block comprises:
an interpolator for interpolating the inputted folding signals and increasing the number of the interpolated folding signals; and
at least one selector for selectively outputting at least one of the interpolated folding signals under the control signal, thereby varying resolution.

3. The A/D Converter as claimed in claim 1, wherein the folding block comprises at least two folding units, and each folding unit comprises at least one folding amplifier for generating the folding signals by a current mirror based on a comparison of the inputted analog signals to reference offset signals.

4. The A/D Converter as claimed in claim 1, further comprising a switching block, interconnecting the interpolation block and the converter block, for switch controlling authorization of the interpolated folding signals, which are outputted from the interpolation block under an external control signal, to the converter block.

5. The A/D Converter as claimed in claim 1, further comprising:
an encoding block for converting the digital signals that are outputted from the converter block to binary data;
an error-correction block for correcting errors in the binary data; and
an output buffer block for buffering an output of the error-corrected binary data.

6. A method for converting analog signals to digital signals, comprising the steps of:
converting inputted analog signals to folding signals;
interpolating the folding signals, adjusting a number of the interpolated folding signals by a predetermined control signal, and outputting the interpolated folding signals; and
converting the interpolated folding signals to digital signals.

7. The method as claimed in claim 6, wherein the interpolating step further comprises the steps of:
increasing a number of folding signals by interpolating the inputted folding signals; and
varying resolution by selectively outputting at least one of the interpolated folding signals.

8. The method as claimed in claim 6, wherein a current mirror generates the folding signals by comparing the inputted analog signals to reference offset signals.

9. The method as claimed in claim 6, further comprising the steps of:
converting the digital signals that are outputted from a converter block to binary data;
correcting errors in the binary data; and
buffering an output of the error-corrected binary data.

10. A receiving device for a terminal in a mobile communication system, mounted with an RF receiver, which is applicable to UMTS (Universal Mobile Telecommunications System : Asynchronous Code Division Multiple Access system) or GSM/GPRS (the Global System for Mobile communications/General Packet Radio Service) mode signals in common and converts RF signals received by the RF receiver to baseband signals, the device comprising:
a digital signal processor for generating a control signal to select at least one of an UMTS or a GSM/GPRS mode; and
an analog to digital converter, which has an interpolation rate fixed by the control signal, converts baseband analog signals outputted from the RF receiver to digital signals, and outputs the digital signals to the digital signal processor, wherein the analog to digital converter comprises:
a folding block for converting inputted analog signals to folding signals;
an interpolation block for interpolating the folding signals, for adjusting a number of the interpolated folding signals by a predetermined control signal and for outputting the interpolated folding signals; and
a converter block for converting the interpolated folding signals to the digital signals.
